(19) United States
(12) Patent Application Publication
(10) Pub. No.: US 2022/0333245 A1
(43) Pub. Date: Oct. 20, 2022

(54) SYSTEMS, METHODS, AND APPARATUS FOR APPLYING A BIAS VOLTAGE TO AN ION BLOCKER PLATE DURING SUBSTRATE PROCESSING OPERATIONS

(71) Applicant: Applied Materials, Inc., Santa Clara, CA (US)

(72) Inventors: Xiaopu LI, San Jose, CA (US); Kallol BERA, Fremont, CA (US); Jay D. PINSON, II, San Jose, CA (US); Martin Jay SEAMONS, San Jose, CA (US)

(21) Appl. No.: 17/235,758

(22) Filed: Apr. 20, 2021

(51) Int. Cl. C23C 16/455; C23C 16/44; H01J 37/32; H01L 21/02

(52) U.S. Cl. CPC C23C 16/45565; C23C 16/4405; H01J 37/32082; H01J 37/32449; H01L 21/02274

(57) ABSTRACT

Aspects generally relate to systems, methods, and apparatus for applying a bias voltage to an ion blocker plate during substrate processing operations. In one aspect, the bias voltage is a negative direct current (DC) voltage. In one aspect, the bias voltage is a radio frequency (RF) voltage having a bias frequency of 2 MHz or less. In one implementation, a system for processing substrates includes a processing chamber. The processing chamber includes a processing volume, a pedestal positioned in the processing volume, and a lid assembly. The system includes a power line coupled to a faceplate of the lid assembly to supply a radio frequency (RF) power to the faceplate. The system includes a bias voltage line coupled to an ion blocker plate of the lid assembly to supply a bias voltage to the ion blocker plate.

### BACKGROUND

### Field

Aspects generally relate to systems, methods, and apparatus for applying a bias voltage to an ion blocker plate during substrate processing operations.

### Description of the Related Art

During substrate processing operations, openings in an ion blocker plate can “light up” (e.g., arcing can occur therein) due to plasma in the openings. Additionally, certain openings might “light up” while others do not. The lighting up can cause non-uniformities in deposition of film thickness on substrates. The lighting up also can cause material of the ion blocker plate to erode at different rates at different locations of the ion blocker plate, which can call for the need to replace the ion blocker plate, resulting in increased costs and machine downtime.

Therefore, there is a need for improved systems, methods, and apparatus that facilitate control of ion density in openings of ion blocker plates to facilitate uniform film deposition, increased ion blocker plate lifespans, reduced costs, reduced machine downtime, increased efficiency, and increased throughput.

### SUMMARY

Aspects generally relate to systems, methods, and apparatus for applying a bias voltage to an ion blocker plate during substrate processing operations. In one aspect, the bias voltage is a negative direct current (DC) voltage. In one aspect, the bias voltage is a radio frequency (RF) voltage having a bias frequency of 2 MHz or less.

In one implementation, a system for processing substrates includes a processing chamber. The processing chamber includes a processing volume, a pedestal positioned in the processing volume, and a lid assembly. The lid assembly includes an ion blocker plate including a plurality of gas openings, and a showerhead positioned between the ion blocker plate and the processing volume. The showerhead includes a plurality of gas openings. The lid assembly includes a faceplate including a plurality of gas openings. The ion blocker plate is positioned between the faceplate and the showerhead. The lid assembly includes a plasma gap positioned between the faceplate and the ion blocker plate, and a gas box. The faceplate is positioned between the gas box and the ion blocker plate. The system includes a power line coupled to the faceplate to supply a radio frequency (RF) power to the faceplate. The system includes a bias voltage line coupled to the ion blocker plate to supply a bias voltage to the ion blocker plate.

In one implementation, a method of processing substrates includes flowing a process gas into a lid assembly of a processing chamber while a substrate is supported on a pedestal positioned in a processing volume of the processing chamber. The lid assembly includes an ion blocker plate including a plurality of gas openings, and a showerhead positioned between the ion blocker plate and the processing volume. The showerhead includes a plurality of gas openings. The lid assembly includes a faceplate including a plurality of gas openings. The ion blocker plate is positioned between the faceplate and the showerhead. The lid assembly includes a plasma gap positioned between the faceplate and the ion blocker plate, and a gas box. The faceplate is positioned between the gas box and the ion blocker plate. The method includes generating a plasma in the plasma gap while flowing the process gas into the lid assembly. The generating the plasma includes supplying a radio frequency (RF) power to the faceplate. The RF power has a source voltage value. The method includes controlling an ion density in the plurality of gas openings of the ion blocker plate. The controlling the ion density includes supplying a bias voltage to the ion blocker plate simultaneously with the supplying the RF power to the faceplate. The bias voltage has a bias voltage value that is less than the source voltage value.

In one implementation, a non-transitory computer readable medium includes instructions. The instructions, when executed, cause a gas source to flow a process gas into a lid assembly of a processing chamber while a substrate is supported on a pedestal positioned in a processing volume of the processing chamber. The lid assembly includes an ion blocker plate including a plurality of gas openings, and a showerhead positioned between the ion blocker plate and the processing volume. The showerhead includes a plurality of gas openings. The lid assembly includes a faceplate including a plurality of gas openings. The ion blocker plate is positioned between the faceplate and the showerhead. The lid assembly includes a plasma gap positioned between the faceplate and the ion blocker plate, and a gas box. The faceplate is positioned between the gas box and the ion blocker plate. The instructions, when executed, cause a power source to generate a plasma in the plasma gap by supplying a radio frequency (RF) power to the faceplate while flowing the process gas into the lid assembly. The RF power has a source voltage value. The instructions, when executed, cause a voltage source to control an ion density in the plurality of gas openings of the ion blocker plate by supplying a bias voltage to the ion blocker plate simultaneously with the supplying the RF power to the faceplate. The bias voltage has a bias voltage value that is less than the source voltage value.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross sectional view of a system for processing substrates, according to one implementation.

FIG. 2 is a schematic top view of the ion blocker plate shown in FIG. 1, according to one implementation.

FIG. 3 is a schematic top view of the showerhead having the plate and the gas distribution plate shown in FIG. 1, according to one implementation.

FIG. 4 is a schematic top view of the gas distribution plate of the showerhead shown in FIG. 1, according to one implementation.

FIG. 5 is a schematic block diagram view of a method of processing substrates, according to one implementation.

FIG. 6 is a schematic view of a graph of ion density measurements taken during a simulated substrate processing operation, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to systems, methods, and apparatus for applying a bias voltage to an ion blocker plate during substrate processing operations. In one aspect, the bias voltage is a negative direct current (DC) voltage. In one aspect, the bias voltage is a radio frequency (RF) voltage having a bias frequency of 2 MHz or less.

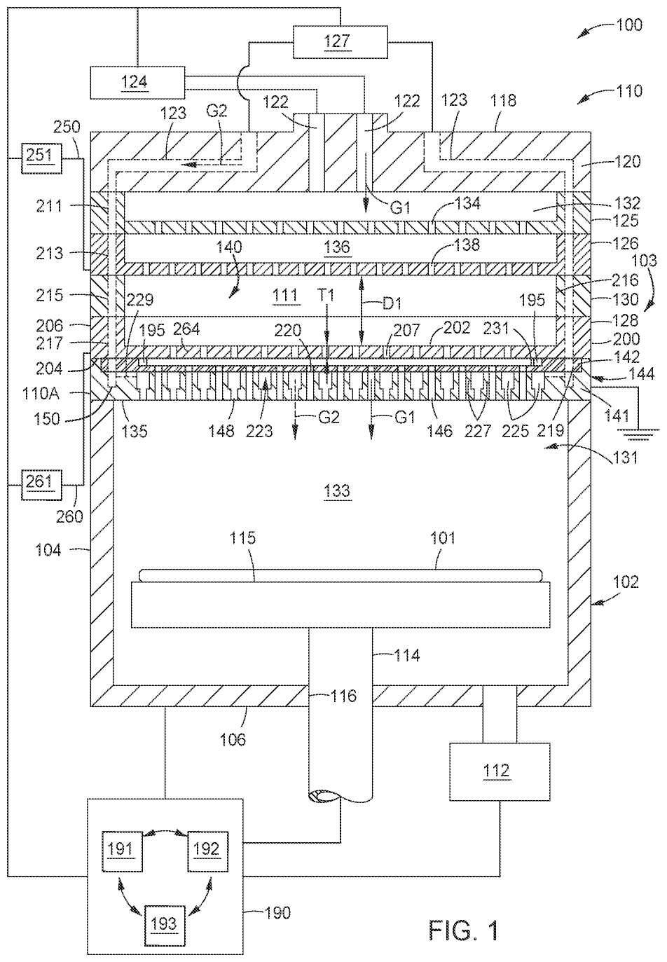

FIG. 1 is a schematic cross sectional view of a system 100 for processing substrates, according to one implementation. The system 100 includes a processing chamber 110. The processing chamber 110 includes a chamber body 102 having one or more sidewalls 104 and a bottom wall 106. The processing chamber 110 includes a lid assembly 103 disposed on the chamber body 102. The processing chamber 110 includes a processing volume 131 defined by the lid assembly 103 and the one or more sidewalls 104, and a pedestal 114 disposed in the processing volume 131. The pedestal 114 can extend through a respective passage 116 formed in the bottom wall 106 of the processing chamber 110. The pedestal 114 includes a substrate support surface 115. The substrate support surface 115 is configured to support a substrate 101 during processing. The pedestal 114 can include substrate lift pins (not shown) disposed through the body of the pedestal 114. The substrate lift pins selectively space the substrate 101 from the pedestal 114 to facilitate exchange of the substrate 101 with a robot (not shown) utilized for transferring the substrate into and out of the processing chamber 110. A vacuum pump 112 is coupled to the processing chamber 110 to exhaust gases, such as processing byproducts, from the processing volume 131.

The processing chamber 110 is a deposition chamber, such as a chemical vapor deposition (CVD) chamber or a plasma-enhanced chemical vapor deposition (PECVD) chamber. Although the processing chamber 100 is shown as a deposition chamber, the present disclosure contemplates that aspects of the present disclosure can be used in other processing chambers, such as an etch chamber, an oxidation chamber, and/or an anneal chamber.

The processing chamber 110 includes an upper manifold 118. The upper manifold 118 may be coupled to a top portion of the chamber body 102, and can be a part of the lid assembly 103. The upper manifold 118 includes a gas box 120 having one or more gas passages 122, 123 (four are shown) formed therein. The gas box 120 is coupled to one or more gas sources 124, 127 (two are shown). The one or more gas sources 124, 127 provide one or more process gases to the processing chamber 110 during processing of the substrate 101.

The lid assembly 103 of the system 100 includes an ion blocker plate 128 having a plurality of gas openings 207, and a showerhead 144 positioned between the ion blocker plate 128 and the processing volume 131. The showerhead 144 includes a plurality of gas openings 146, 148. The lid assembly 103 includes a faceplate 126 having a plurality of gas openings 138. The ion blocker plate 128 is positioned between the faceplate 126 and the showerhead 144. The lid assembly 103 also includes a spacer 130 positioned between the faceplate 126 from the ion blocker plate 128. The faceplate 126 is positioned between the gas box 120 and the ion blocker plate 128. The ion blocker plate 128 can include a coating, such as a protective coating, disposed thereon to facilitate protecting the ion blocker plate 128 from contamination and/or erosion by the first process gases G1. The coating also facilitates reduced likelihood of radical recombination.

A portion of the ion blocker plate 128 that includes the gas openings 207 formed therein has a thickness T1 that is within a range of 1 mm to 5 mm, such as 4 mm. The gas openings 207 each include a diameter that is within a range of 1 mm to 5 mm, such as 3 mm. The gas openings 207 are spaced apart from each other by an opening-to-opening distance that is within a range of 5 mm to 10 mm, such as 8 mm. The portion of the ion blocker plate 128 having the gas opening 207 is spaced from the faceplate 126 by a distance D1 that is within a range of 10 mm to 40 mm, such as 25 mm.

In one embodiment, which can be combined with other embodiments, the lid assembly 103 can optionally include a blocker plate 125 positioned between the faceplate 126 and the gas box 120. A first plenum 132 is positioned between the optional blocker plate 125 and the gas box 120. The first plenum 132 is configured to receive one or more first process gases G1 from one or more first gas passages 122. The one or more first process gases G1 include one or more plasma gases, such as oxygen and/or argon. The first process gases G1 are flowed into the first gas passages 122 of the gas box 120 from a first gas source 124. The first process gases G1 flow from the first plenum 132 and through the blocker plate 125 via the gas openings 134 formed in the blocker plate 125. The gas openings 134 are configured to allow for passage of gas from a top side of the blocker plate 125 to a bottom side of the blocker plate 125. The faceplate 126 and the optional blocker plate 125 are a part of an upper showerhead that is disposed above the showerhead 144.

The faceplate 126 is positioned beneath the blocker plate 125. A second plenum 136 is positioned between the faceplate 126 and the blocker plate 125. The gas openings 134 of the blocker plate 125 are in fluid communication with the second plenum 136. The first process gases G1 is flowed through the blocker plate 125 via the gas openings 134 and into the second plenum 136. From the second plenum 136, the first process gases flow through the faceplate 126 via the gas openings 138 formed in the faceplate 126.

The ion blocker plate 128 is positioned beneath the faceplate 126. The spacer 130 separates the ion blocker plate 128 from the faceplate 126. A plasma gap 111 is positioned between the faceplate 126 and the ion blocker plate 128. The spacer 130 may be an insulating ring that allows an alternating current (AC) potential to be applied to the faceplate 126 relative to the ion blocker plate 128. The spacer 130 may be positioned between the faceplate 126 and the ion blocker plate 128 to enable a capacitively coupled plasma (CCP) to be formed in the plasma gap 111. The plasma gap 111 is a third plenum 140 positioned between the faceplate 126 and the ion blocker plate 128. The plasma gap 111 is configured to receive the first process gases G1 from the second plenum 136 via the gas openings 138 formed in the faceplate 126.

The faceplate 126 and the ion blocker plate 128 act as two electrodes of RFs and the spacer 130 acts as an isolator between the faceplate 126 and the ion blocker plate 128. A plasma field is formed in the plasma gap 111 between the two electrodes (e.g., the faceplate 126 and the ion blocker plate 128). The one or more first process gases G1 are dissociated in the plasma field of the plasma gap 111. The gas openings 138 formed in the faceplate 126 allow the first process gases G1 to enter the plasma field in the plasma gap 111. A plasma is generated in the plasma gap 111.

The gas openings 207 of the ion blocker plate 128 include apertures formed through the ion blocker plate 128. The gas openings 207 are configured to suppress (e.g., block) the migration of ionically charged species (e.g., ions) of the plasma through the ion blocker plate 128, while allowing uncharged neutral or radical species (e.g., radicals) of the plasma to pass through the ion blocker plate 128 and into the processing volume 131 of the processing chamber 110 during a processing operation that processes the substrate 101. In one example, which can be combined with other examples, the radicals are oxygen radicals.

The showerhead 144 is positioned beneath the ion blocker plate 128. A lower surface 135 of the showerhead 144 defines an upper boundary of the processing volume 131. The processing volume 131 includes a processing region 133 disposed between the pedestal 114 and the lower surface 135 of the showerhead 144. The showerhead 144 is an assembly that includes a gas distribution plate 141 and a plate 142 received in a recessed formed in an upper surface of the gas distribution plate 141. The present disclosure contemplates that the gas distribution plate 141 and the plate 142 can be integrally formed as a single body for the showerhead 144. The gas distribution plate 141 is a faceplate of the showerhead 144.

The present disclosure contemplates that the faceplate 126 and/or the blocker plate 125 (if used) can be integrally formed with the gas box 120 as a single body.

As shown in the implementation shown in FIG. 1, the showerhead 144 can be a dual channel shower head. The gas distribution plate 141 of the showerhead 144 includes a plurality of first gas openings 146, a plurality of second gas openings 148, and one or more gas passages 150 formed in the gas distribution plate 141. The plurality of first gas openings 146 is in fluid communication with the gas openings 207 formed in the ion blocker plate 128. The plurality of first gas openings 146 allow for radicals (that flow past the gas openings 207) in the first process gases G1 of the plasma formed in the plasma gap 111 to travel through the showerhead 144 and into the processing region 133 of the processing volume 131.

The one or more gas passages 150 are configured to receive one or more second process gases G2 from a second gas source 127. The second process gases G2 include one or more precursor gases that react with the radicals of the first process gases G1 in the processing region 133 of the processing volume 131. The one or more precursor gases react with the radicals to facilitate deposition of film onto the substrate 101. The one or more precursor gases can include octamethylcyclotetrasiloxane (OMCTS), for example. The one or more second process gases G2 flow into one or more second gas passages 123 of the gas box 120 of the lid assembly 103.

The plurality of second gas openings 148 are formed in the showerhead 144 such that the plurality of second gas openings 148 provide fluid communication between the one or more gas passages 150 and the processing region 133 of the processing volume 131. As such, the radicals that exit the plasma gap 111 and enter the processing region 133 of the processing volume 131 via the plurality of first gas openings 146 may mix and react with the precursor gases provided by the one or more gas passages 150 via the plurality of second gas openings 148. The second process gases G2 (the precursor gases) and the first process gases G1 (having the radicals) do not enter the plasma gap 111 together and react therein. Rather, because the showerhead 144 is positioned below the ion blocker plate 128, the first process gases G1 exit the plasma gap 111 first, and then enter into the showerhead 144. Thus, the mixing and reaction between first process gases G1 and the second process gases G2 are outside of the plasma gap 111. As such, the combination of indirect capacitively coupled plasma and the later introduced precursor provides a better gap-fill and wider film flowability window.

The blocker plate 125 (if used) includes a plurality of outer gas openings 211 disposed outside of the gas openings 134. The outer gas openings 211 of the blocker plate 125 are vertically aligned with vertical sections of the one or more second gas passages 123. The faceplate 126 includes a plurality of outer gas openings 213 disposed outside of the gas openings 138. The outer gas openings 213 of the faceplate 126 are vertically aligned with the outer gas openings 211 of the blocker plate 125 (if used). The spacer 130 includes a plurality of outer gas openings 215 disposed outside of a central opening 216 that is a part of the plasma gap 111. The outer gas openings 215 of the spacer 130 are vertically aligned with the outer gas openings 213 of the faceplate 126. The ion blocker plate 128 includes a plurality of outer gas openings 217 disposed outside of the gas openings 207. The outer gas openings 217 of the ion blocker plate 128 are vertically aligned with the outer gas openings 215 of the spacer 130. The plate 142 includes a plurality of outer gas openings 219 disposed outside of a plurality of gas openings 220. The outer gas openings 219 of the plate 142 are vertically aligned with the outer gas openings 217 of the ion blocker plate 128. The one or more gas passages 150 of the gas distribution plate 141 are vertically aligned with the outer gas openings 219 of the plate 142. If the plate 142 is integrally formed with the gas distribution plate 141, the outer gas openings 219 are combined with the one or more gas passages 150.

The gas openings 220 of the plate 142 are vertically aligned with the first gas openings 146 of the gas distribution plate 141 to allow the one or more first process gases G1 to flow from the gas openings 207 of the ion blocker plate 128 and into the processing region 133 of the processing volume 131. The one or more second process gases G2 flow into the one or more second gas passages 123, through the outer gas openings 211, through the outer gas openings 213, through the outer gas openings 215, through the outer gas openings 217, through the outer gas openings 219, and into the one or more gas passages 150. The one or more second gases G2 flow from the one or more gas passages and into a showerhead plenum 223. The showerhead plenum 223 is disposed between the plate 142 and the gas distribution plate 141. The showerhead plenum 223 includes a plurality of gaps 225 between and outside of a plurality of bosses 227 that extend between the plate 142 and the gas distribution plate 141. The one or more second gases G2 flow from the one or more gas passages 150 and into the showerhead plenum 223 through one or more wall openings 229 formed in the gas distribution plate 141. The first gas openings 146 of the gas distribution plate 141 extend through the bosses 227.

As shown in FIG. 1, the gas openings 207 of the ion blocker plate 128 can be vertically offset from the gas openings 220 of the plate 142 to facilitate reducing the amount of ions that flow downward past the gas openings 220. In such an embodiment, the plate 142 includes an upper recess 231 to allow the one or more first process gases G1 to flow from the gas openings 207 and into the gas openings 220. Alternatively, the upper recess 231 can be omitted from the plate 142, and the gas openings 207 of the ion blocker plate 128 can be vertically aligned with the gas openings 220 of the plate 142 to allow the one or more first process gases G1 to flow from the gas openings 207 and into the gas openings 220.

The system 100 includes a power line 250 coupled to the faceplate 126 to supply a radio frequency (RF) power to the faceplate 126. The RF power supplied to the faceplate 126 while the one or more process gases G1 flow through the lid assembly 103 to generate the plasma in the plasma gap 111. The RF power has a source voltage value and a frequency. The power line 250 is coupled to a power source 251 that is configured to generate the RF power and supply the RF power to the faceplate 126 through the power line 250. The frequency of the RF power is within a range of 10 MHz to 30 MHz, such as within a range of 13.5 MHz to 13.7 MHz. The source voltage value of the RF power is within a range of 200 Volts to 600 Volts. The RF power has a power value that is within a range of 150 Watts to 250 Watts, such as 200 Watts. The source voltage value is maintained relative to the showerhead 144, such as maintained relative to an upper surface 204 of the gas distribution plate 141.

The one or more first process gases G1 flow through the lid assembly 103 at a pressure within a range of 1 Torr to 3 Torr, such as 2 Torr. The one or more first process gases G1 flow into the gas box 120 with a gas composition having a flow rate ratio of argon:oxygen that is 20:80. The argon flows into the gas box 120 at a flow rate of about 250 standard cubic centimeters per minute (SCCM), and the oxygen flows into the gas box 120 at a flow rate of about 1,000 SCCM.

The system 100 also includes a bias voltage line 260 coupled to the ion blocker plate 128 to supply a bias voltage to the ion blocker plate 128. The bias voltage is supplied to the ion blocker plate 128 simultaneously with the supplying of the RF power to the faceplate 126. The bias voltage supplied to the ion blocker plate 128 controls an ion density in each of the plurality of gas openings 207 of the ion blocker plate 128 to reduce the amount of ions that flow downward past the gas openings 207. The bias voltage has a bias voltage value that is less than the source voltage value.

The bias voltage line 260 is coupled to a voltage source 261 that is configured to generate the bias voltage and supply the bias voltage to the ion blocker plate 128 through the bias voltage line 260. The bias voltage line 260 is coupled to one or more electrodes 264, such as one or more wire meshes, embedded in the ion blocker plate 128. The gas openings 207 can be divided and grouped into a plurality of zones. The controller 190 and the voltage source 261 can be configured to deliver different bias voltages (such as different bias voltage values) to different zones having different gas openings 207.

The bias voltage is a direct current (DC) voltage or an RF voltage. The DC voltage is a negative DC voltage that is negative relative to the showerhead 144, such as negative relative to the upper surface 204 of the gas distribution plate 141. The showerhead 144, such as the gas distribution plate 141, is grounded. The negative DC voltage has a negative bias voltage value that is within a range of 0 Volts to −50 Volts, such as −5 Volts to −15 Volts, for example −10 Volts. The negative bias voltage value is selected such that the DC voltage does not ignite plasma, such as in the gas openings 207.

The RF voltage has a bias frequency of 2 MHz or less, such as within a range of 100 kHz to 2 MHz. In one embodiment, which can be combined with other embodiments, the bias frequency of the RF voltage is within a range of 350 kHz to 450 kHz, such as within a range of 380 kHz to 400 kHz. The RF voltage has a bias voltage value of 50 Volts or less. In one embodiment, which can be combined with other embodiments, the bias voltage value is 50 Volts or less, such as within a range of 5 Volts to 15 Volts, for example 10 Volts. In one embodiment, which can be combined with other embodiments, the bias voltage value of the bias voltage supplied to the ion blocker plate 128 is equal to or less than 20% of the source voltage value of the RF power supplied to the faceplate 126. The bias voltage value and the bias frequency are selected such that the RF voltage does not ignite plasma, such as in the gas openings 207. The bias voltage value is maintained relative to the showerhead 144, such as maintained relative to the upper surface 204 of the gas distribution plate 141.

The system 100 includes a controller 190 to control the operations of the system 100. The controller 190 is coupled to the power source 251, the voltage source 261, the first gas source 124, the second gas source 127, the pedestal 114, and the vacuum pump 112 to control the operations thereof. The controller 190 includes a central processing unit (CPU) 191, a memory 192 containing instructions, and support circuits 193 for the CPU 191. The controller 190 controls the system 100 directly, or via other computers and/or controllers (not shown) coupled to the processing chamber 110. The controller 190 is of any form of a general-purpose computer processor that is used in an industrial setting for controlling various chambers and equipment, and sub-processors thereon or therein.

The memory 192, or non-transitory computer readable medium, is one or more of a readily available memory such as random access memory (RAM), read only memory (ROM), floppy disk, hard disk, flash drive, or any other form of digital storage, local or remote. The support circuits 193 are coupled to the CPU 191 for supporting the CPU 191 (a processor). The support circuits 193 include cache, power supplies, clock circuits, input/output circuitry and subsystems, and the like. Substrate processing parameters and operations are stored in the memory 192 as a software routine that is executed or invoked to turn the controller 190 into a specific purpose controller to control the operations of the system 100. The controller 190 is configured to conduct any of the methods and operations described herein. The instructions stored in the memory 192, when executed, cause one or more of operations 502-508 of method 500 to be conducted.

As an example, the instructions stored in the memory 192, when executed, cause the power source 251 to generate the RF power and supply the RF power to the faceplate 126 through the power line 250 to generate the plasma in the plasma gap 111. The instructions also, when executed, cause the voltage source 261 to generate the negative DC voltage and supply the negative DC voltage to the ion blocker plate 128 through the bias voltage line 260 to control an ion density in each of the plurality of gas openings 207 of the ion blocker plate 128.

As another example, the instructions stored in the memory 192, when executed, cause the power source 251 to generate the RF power at the frequency and the source voltage value, and supply the RF power to the faceplate 126 through the power line 250 to generate the plasma in the plasma gap 111. The instructions also, when executed, cause the voltage source 261 to generate the RF voltage at the bias frequency and the bias voltage value, and supply the RF voltage to the ion blocker plate 128 through the bias voltage line 260 to control an ion density in each of the plurality of gas openings 207 of the ion blocker plate 128.

The system 100 includes one or more sensors 195 to measure an ion density of the one or more first process gases G1 in the gas openings 207 and/or downstream of the gas openings 207. The one or more sensors 195 (two are shown in FIG. 1) are disposed in the upper recess 231 and below the ion blocker plate 128. The one or more sensors 195 can be disposed in the processing volume 131 and mounted to inner surface(s) of the one or more sidewalls 104 to measure an ion density in the processing volume 131.

The plurality of instructions executed by the controller 190 include instructions that instruct the one or more sensors 195 to detect, monitor, and/or measure the ion density. The one or more sensors 195 can be disposed in other locations (such as to facilitate a line of sight to the substrate 101) and can measure properties of the substrate 101, such as film thickness and/or film uniformity. As an example, the one or more sensors 195 can be disposed in or adjacent a transparent window of the processing chamber 110 to facilitate a line of sight to the substrate 101. The one or more sensors 195 include one or more particle counters, metrology sensors, on-substrate spectroscopy sensors (such as X-ray fluorescence spectroscopy (XRF) sensors and/or X-ray photoelectron spectroscopy (XPS) sensors), cameras, and/or optical sensors (such as laser sensors). Sensors outside of the processing chamber 110, such as sensors coupled to a second chamber (for example a measurement chamber, a load lock chamber, a transfer chamber, a buffer chamber, an interface chamber, or a factory interface chamber), which are similar to the sensors 195 can also measure the properties of the substrate 101.

The instructions in the memory 192 of the controller 190 can include one or more machine learning/artificial intelligence algorithms that can be executed in addition to the operations described herein. As an example, a machine learning/artificial intelligence algorithm executed by the controller 190 can optimize and alter operational parameters based on the ion density measurements and/or the substrate property measurements taken by the one or more sensors 195 and/or the sensors coupled to the second chamber. The operational parameters can include for example, the frequency of the RF power, the source voltage value of the RF power, the negative bias voltage value of the DC voltage, the bias frequency of the RF voltage, the bias voltage value of the RF voltage, and/or the flow rates of the one or more process gases G1.

The one or more machine learning/artificial intelligence algorithms can account for the measured ion density, the measured substrate properties, and/or the measured radical density to optimize the operational parameters such as the negative bias voltage value of the DC voltage, the bias frequency of the RF voltage, and/or the bias voltage value of the RF voltage used for the bias voltage. As an example, the one or more machine learning/artificial intelligence algorithms can use the measured ion density, the measured substrate properties, and/or the measured radical density from previous iterations of substrate processing operations to determine an optimized negative bias voltage value, an optimized bias frequency, and/or an optimized bias voltage value to be used for the bias voltage supplied to the ion blocker plate 128 in a subsequent substrate processing operation. The one or more machine learning/artificial intelligence algorithms can be executed by the controller 190.

The one or more machine learning/artificial intelligence algorithms can cause the processing chamber 110 to conduct substrate processing operations and alter the bias voltage during substrate processing operations. While altering the bias voltage, the one or more machine learning/artificial intelligence algorithms can detect and measure a trend in the measured ion density, the measured substrate properties, and/or the measured radical density to determine one or more optimized operational parameters. In one example, which can be combined with other examples, the controller 190 is configured to determine an X:Y ratio of the measured ion density “X” relative to the measured radical density “Y” and optimize the bias voltage such that “X” is equal to or less than 10¹⁶ and “Y” is 10¹⁹ or greater. In one example, which can be combined with other examples, the bias voltage is optimized such as the X:Y ratio is equal to 0.001 or less (e.g., “X” is 0.001 or less of “Y”).

The bias voltage line 260 is coupled to one or more electrodes 264, such as one or more wire meshes, embedded in the ion blocker plate 128. The gas openings 207 can be divided and grouped into a plurality of zones. The controller 190 and the voltage source 261 can be configured to deliver different bias voltages (such as different bias voltage values) to different zones having different gas openings 207.

The controller 190 can group the gas openings 207 into a plurality of zones use the one or more machine learning/artificial intelligence algorithms to determine an optimized bias voltage for each individual zone of the plurality of zones.

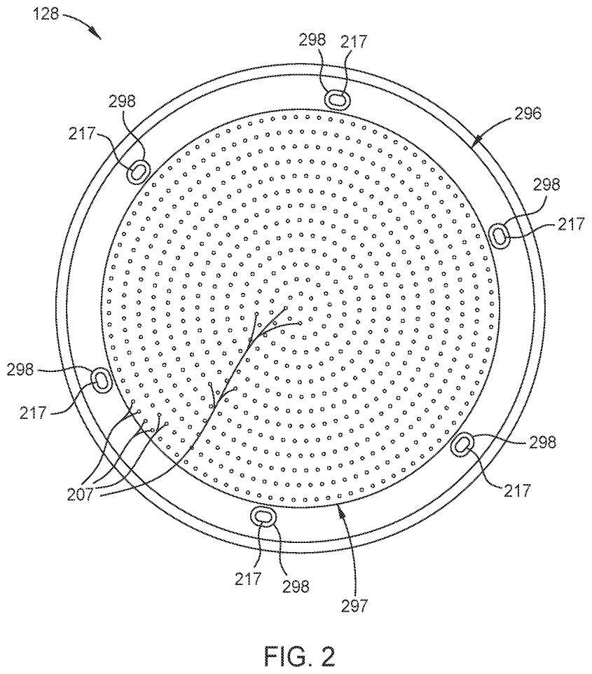

FIG. 2 is a schematic top view of the ion blocker plate 128 shown in FIG. 1, according to one implementation. The gas openings 207 are disposed in a concentric circular pattern on the ion blocker plate 128. The ion blocker plate 128 includes the outer gas openings 217 disposed circumferentially on the ion blocker plate 128. The outer gas openings 217 are disposed radially outside of the gas openings 207. The outer gas openings 217 are oblong in shape. The gas openings 207 are circular in shape. The outer gas openings 217 are formed in bosses 298, respectively. The bosses 298 protrude from the ion blocker plate 128. The ion blocker plate 128 can include an inner shoulder 297 and an outer shoulder 296.

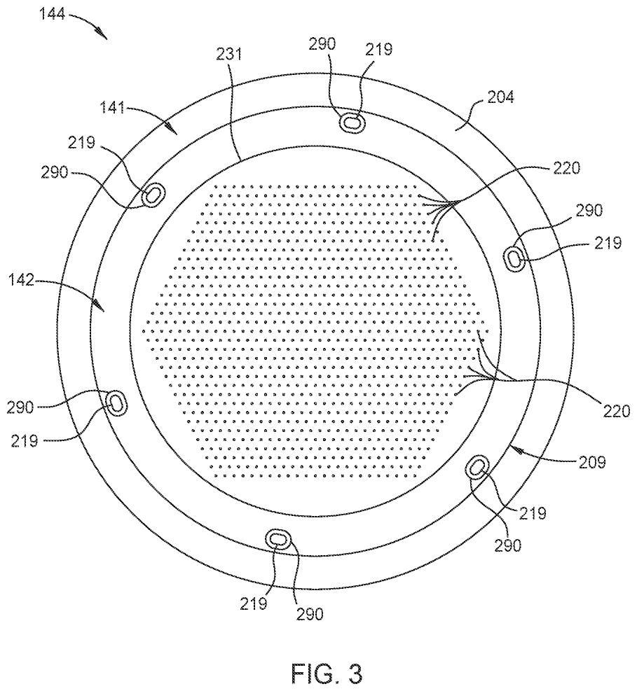

FIG. 3 is a schematic top view of the showerhead 144 having the plate 142 and the gas distribution plate 141 shown in FIG. 1, according to one implementation. The plate 142 is disposed within an inner shoulder 209 of the gas distribution plate 141. The gas openings 220 are disposed in a hexagonal pattern on the plate 142. The outer gas openings 219 are disposed circumferentially on the plate 142. The outer gas openings 219 are disposed radially outside of the gas openings 220. The outer gas openings 219 are oblong in shape. The gas openings 220 are circular in shape. The outer gas openings 219 are formed in bosses 290, respectively. The bosses 290 protrude from the plate 142.

The present disclosure contemplates that the openings, and/or channels disclosed herein may be a variety of shapes, such as circular or oblong. The shapes of the openings and/or the channels may be used to accommodate various flow rates of the first process gases G1 and the second process gases G2, and may be used to facilitate producing seals between components or features of lid assembly 103. The shapes and sizes of the openings and/or the channels disclosed herein may be modified based on process requirements for the substrate 101, the processing chamber 110, the first process gases G1, and/or the second process gases G2.

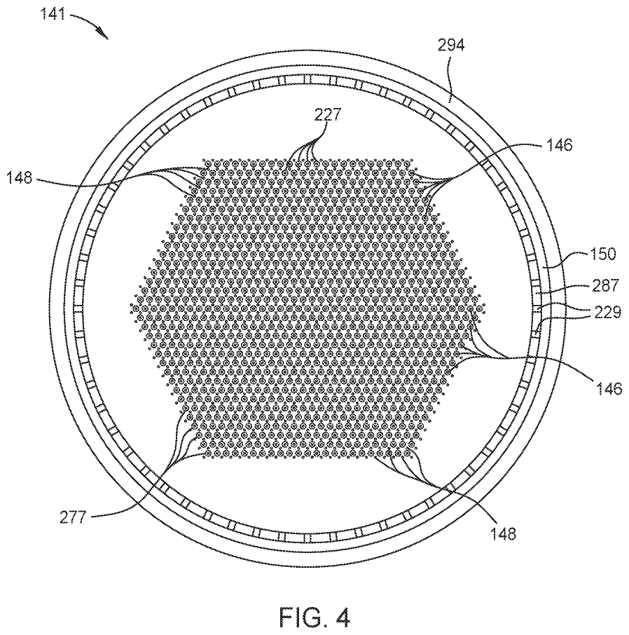

FIG. 4 is a schematic top view of the gas distribution plate 141 of the showerhead 144 shown in FIG. 1, according to one implementation. The gas distribution plate 141 includes the one or more gas passages 150 (one is shown) disposed circumferentially around the first gas openings 146, the bosses 227, and the second gas openings 148. The one or more gas passages 150 are one or more gas channels. The second gas openings 148 are disposed around and between the bosses 227. The second gas openings 148 are separated from the one or more gas passages 150 by a wall 287 of the gas distribution plate 141. The wall openings 229 (a plurality are shown) allow the second process gases G2 to flow from the one or more gas passages 150 and into the second gas openings 148. In one example, which can be combined with other examples, the bosses 227, the first gas openings 146, and the second gas openings 148 are disposed in a hexagonal arrangement on the gas distribution plate 141, as shown in FIG. 4.

Although the present disclosure illustrates openings and channels in various orientations and configurations, the present disclosure contemplates that other orientations and/or configurations are possible. For example, the present disclosure contemplates that the plates, the showerhead, the manifolds, the gas box, the openings, and/or the channels disclosed herein can involve various shapes, sizes, numbers of iterations, lengths, dimensions, vertical orientations, horizontal orientations, and/or angled orientations.

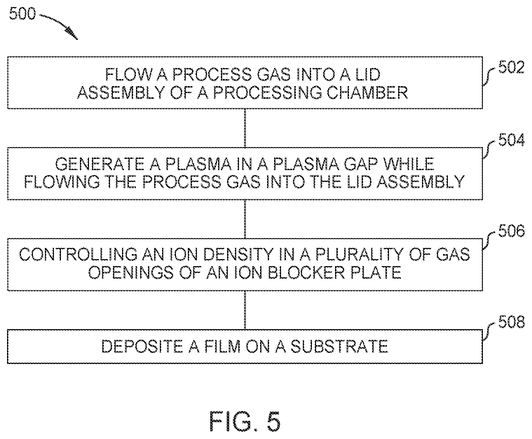

FIG. 5 is a schematic block diagram view of a method 500 of processing substrates, according to one implementation. The method 500 can be used in relation to the system 100 shown in FIG. 1, for example.

Operation 502 includes flowing a process gas into a lid assembly of a processing chamber while a substrate is supported on a pedestal positioned in a processing volume of the processing chamber. The lid assembly includes an ion blocker plate that includes a plurality of gas openings, and a showerhead positioned between the ion blocker plate and the processing volume. The showerhead includes a plurality of gas openings. The lid assembly includes a faceplate that includes a plurality of gas openings. The ion blocker plate is positioned between the faceplate and the showerhead. The lid assembly includes a plasma gap positioned between the faceplate and the ion blocker plate, and a gas box. The faceplate is positioned between the gas box and the ion blocker plate.

Operation 504 includes generating a plasma in the plasma gap while flowing the process gas into the lid assembly. The generating the plasma includes supplying a radio frequency (RF) power to the faceplate. The RF power has a source voltage value.

Operation 506 includes controlling an ion density in the plurality of gas openings of the ion blocker plate. The controlling the ion density includes supplying a bias voltage to the ion blocker plate simultaneously with the supplying the RF power to the faceplate of operation 504. The bias voltage has a bias voltage value that is less than the source voltage value of the RF power. The bias voltage is a direct current (DC) voltage or an RF voltage. The DC voltage is a negative DC voltage.

Operation 508 includes depositing a film on the substrate while the substrate is supported on the pedestal. The film is deposited on the substrate while the ion density is controlled in operation 506.

The present disclosure contemplates that parameters described herein can be used for the method 500. As an example, the frequency of the RF power, the source voltage value of the RF power, the negative bias voltage value of the DC voltage, the bias frequency of the RF voltage, the bias voltage value of the RF voltage, and/or the flow rates of the one or more process gases G1 can be used in the method 500.

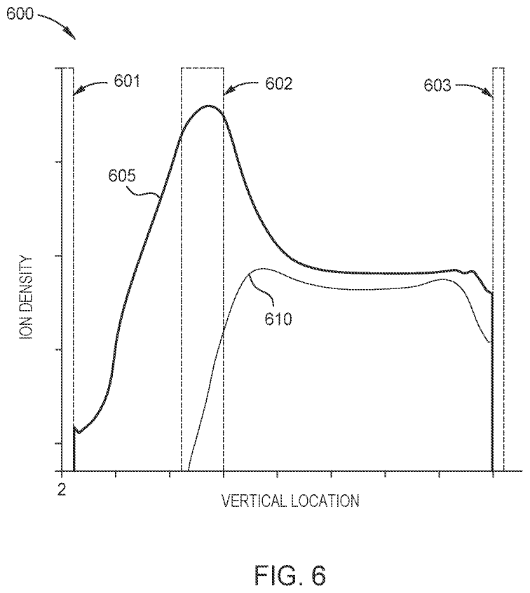

FIG. 6 is a schematic view of a graph 600 of ion density measurements taken during a simulated substrate processing operation, according to one implementation. The Y-axis indicates ion density values, and the X-axis indicates a vertical location from the dual channel showerhead 144 and upwards towards the faceplate 126. A first zone 601 corresponds to the plate 142, a second zone 602 corresponds to a gas opening 207 of the ion blocker plate 128, and a third zone 603 corresponds to the faceplate 126. In a first profile 605, the ion density measurements were taken while the RF power was supplied to the faceplate 126, but the bias voltage was not supplied to the ion blocker plate 128. In a second profile 610, the ion density measurements were taken while the RF power was supplied to the faceplate 126, and the bias voltage was supplied to the ion blocker plate 128.

The graph 600 illustrates that, using the bias voltage described herein, the ion density is reduced during processing across the vertical locations between the dual channel showerhead 144 and the faceplate 126, including in the gas openings 207 of the ion blocker plate 128. The reduced ion density in the gas openings 207—and downstream thereof—facilitates increased lifespans for the ion blocker plate 128 and enhanced deposition uniformity of film on the substrate 101 in the downstream processing region 133 of the processing volume 131.

Benefits of the present disclosure include reduced occurrences of plasma light-up in gas openings of ion blocker plates, control of ion density in gas openings of ion blocker plates, uniform film deposition on substrates, increased ion blocker plate lifespans, reduced costs, reduced machine downtime, increased efficiency, and increased throughput. As an example, controlling ion density in the gas openings reduces the likelihood of non-uniform erosion of the ion blocker plates, reducing the frequency of replacement (reducing machine downtime) and replacement costs (increasing operational efficiency). As another example, the present disclosure facilitates reduced ion densities in the gas openings (and downstream thereof) while maintaining radical densities at beneficial levels for purposes of reaction and film deposition. The present disclosure facilitates the benefits described while a coating is used on ion blocker plates.

It is contemplated that one or more aspects disclosed herein may be combined. As an example, one or more aspects, features, components, and/or properties of the system 100, the lid assembly 103, and/or the method 500 may be combined. Moreover, it is contemplated that one or more aspects disclosed herein may include some or all of the aforementioned benefits.

Operational parameters disclosed herein (such as the frequency of the RF power, the source voltage value of the RF power, the negative bias voltage value of the DC voltage, the bias frequency of the RF voltage, the bias voltage value of the RF voltage, and/or the flow rates of the one or more process gases G1) facilitate the benefits described.

The operational parameters disclosed herein facilitate unexpected results because it is previously believed that applying voltage to the ion blocker plate can substantially hinder film deposition or cause non-uniform film deposition on substrates, and can even result in no deposition of film on substrates. It is also previously believed that applying voltage to the ion blocker plate can reduce radical densities below beneficial levels. However, as an example, using the parameters disclosed herein facilitates reduced ion densities while maintaining radical densities at beneficial levels to facilitate achieving increased ion blocker plate lifespans while facilitating achieving uniform film deposition at target film thicknesses. For example, using the DC voltage (having the negative DC voltage) or the RF voltage (having the bias frequency) as the bias voltage increased a plasma sheet thickness of the plasma to prevent plasma from moving downward into the gas openings 207 of the ion blocker plate 128 (reducing plasma light-up in the gas openings 207) while maintaining radical densities at beneficial levels.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A system for processing substrates, comprising:
a processing chamber comprising a processing volume, a pedestal positioned in the processing volume, and a lid assembly, the lid assembly comprising:
an ion blocker plate comprising a plurality of gas openings,
a showerhead positioned between the ion blocker plate and the processing volume, the showerhead comprising a plurality of gas openings,
a faceplate comprising a plurality of gas openings, the ion blocker plate being positioned between the faceplate and the showerhead,
a plasma gap positioned between the faceplate and the ion blocker plate, and
a gas box, the faceplate being positioned between the gas box and the ion blocker plate;
a power line coupled to the faceplate to supply a radio frequency (RF) power to the faceplate; and
a bias voltage line coupled to the ion blocker plate to supply a bias voltage to the ion blocker plate.

2. The system of claim 1, further comprising:
a power source coupled to the power line and configured to generate the RF power; and
a voltage source coupled to the bias voltage line and configured to generate the bias voltage.

3. The system of claim 2, wherein the bias voltage is a direct current (DC) voltage or an RF voltage.

4. The system of claim 3, wherein the DC voltage is a negative DC voltage.

5. The system of claim 4, wherein the negative DC voltage has a negative bias voltage value that is within a range of 0 Volts to −50 Volts.

6. The system of claim 5, further comprising a controller comprising a plurality of instructions that, when executed by a processor, cause:
the power source to generate the RF power and supply the RF power to the faceplate through the power line to generate a plasma in the plasma gap, and
the voltage source to generate the negative DC voltage and supply the negative DC voltage to the ion blocker plate through the bias voltage line to control an ion density in the plurality of gas openings of the ion blocker plate.

7. The system of claim 3, wherein the RF voltage has a bias frequency of 2 MHz or less, and a bias voltage value of 50 Volts or less.

8. The system of claim 7, wherein the bias voltage value is 50 Volts or less.

9. The system of claim 7, wherein the RF power has a frequency within a range of 10 MHz to 30 MHz, and a source voltage value within a range of 200 Volts to 600 Volts.

10. The system of claim 9, further comprising a controller comprising a plurality of instructions that, when executed by a processor, cause:
the power source to generate the RF power at the frequency and the source voltage value, and supply the RF power to the faceplate through the power line to generate a plasma in the plasma gap, and
the voltage source to generate the RF voltage at the bias frequency and the bias voltage value, and supply the RF voltage to the ion blocker plate through the bias voltage line to control an ion density in the plurality of gas openings of the ion blocker plate.

11. A method of processing substrates, comprising:
flowing a process gas into a lid assembly of a processing chamber while a substrate is supported on a pedestal positioned in a processing volume of the processing chamber, the lid assembly comprising:
an ion blocker plate comprising a plurality of gas openings,
a showerhead positioned between the ion blocker plate and the processing volume, the showerhead comprising a plurality of gas openings,
a faceplate comprising a plurality of gas openings, the ion blocker plate being positioned between the faceplate and the showerhead,
a plasma gap positioned between the faceplate and the ion blocker plate, and
a gas box, the faceplate being positioned between the gas box and the ion blocker plate;
generating a plasma in the plasma gap while flowing the process gas into the lid assembly, the generating the plasma comprising:
supplying a radio frequency (RF) power to the faceplate, the RF power having a source voltage value; and
controlling an ion density in the plurality of gas openings of the ion blocker plate, the controlling the ion density comprising:
supplying a bias voltage to the ion blocker plate simultaneously with the supplying the RF power to the faceplate, the bias voltage having a bias voltage value that is less than the source voltage value.

12. The method of claim 11, wherein the bias voltage is a direct current (DC) voltage or an RF voltage.

13. The method of claim 12, wherein the DC voltage is a negative DC voltage.

14. The method of claim 12, wherein the RF voltage has a bias frequency of 2 MHz or less, and a bias voltage value of 50 Volts or less.

15. The method of claim 14, wherein the RF power has a frequency within a range of 10 MHz to 30 MHz, and a source voltage value within a range of 200 Volts to 600 Volts.

16. A non-transitory computer readable medium comprising instructions that, when executed, cause:
a gas source to flow a process gas into a lid assembly of a processing chamber while a substrate is supported on a pedestal positioned in a processing volume of the processing chamber, the lid assembly comprising:
an ion blocker plate comprising a plurality of gas openings,
a showerhead positioned between the ion blocker plate and the processing volume, the showerhead comprising a plurality of gas openings,
a faceplate comprising a plurality of gas openings, the ion blocker plate being positioned between the faceplate and the showerhead,
a plasma gap positioned between the faceplate and the ion blocker plate, and
a gas box, the faceplate being positioned between the gas box and the ion blocker plate;
a power source to generate a plasma in the plasma gap by supplying a radio frequency (RF) power to the faceplate while flowing the process gas into the lid assembly, the RF power having a source voltage value; and
a voltage source to control an ion density in the plurality of gas openings of the ion blocker plate by supplying a bias voltage to the ion blocker plate simultaneously with the supplying the RF power to the faceplate, the bias voltage having a bias voltage value that is less than the source voltage value.

17. The non-transitory computer readable medium of claim 16, wherein the bias voltage is a direct current (DC) voltage or an RF voltage.

18. The non-transitory computer readable medium of claim 17, wherein the DC voltage is a negative DC voltage.

19. The non-transitory computer readable medium of claim 17, wherein the RF voltage has a bias frequency of 2 MHz or less, and a bias voltage value of 50 Volts or less.

20. The non-transitory computer readable medium of claim 19, wherein the RF power has a frequency within a range of 10 MHz to 30 MHz, and a source voltage value within a range of 200 Volts to 600 Volts.
